(19) United States
(12) Patent Application Publication
(10) Pub. No.: US 2017/0125381 A1
(43) Pub. Date: May 4, 2017

(54) SYSTEM OF AT LEAST TWO MICROCONTROLLERS, AND METHOD FOR PRODUCING SUCH A SYSTEM

(71) Applicant: Robert Bosch GmbH, Stuttgart (DE)

(72) Inventors: Axel Aue, Korntal-Muenchingen (DE); Hans-Walter Schmitt, Weissach/Flacht (DE); Nico Bannow, Stuttgart (DE)

(21) Appl. No.: 15/333,956

(22) Filed: Oct. 25, 2016

(30) Foreign Application Priority Data
Oct. 28, 2015 (DE) 102015221064.2

(51) Int. Cl. H01L 25/065; G06F 13/42; H01L 25/10

(52) U.S. Cl. CPC H01L 25/0655; H01L 25/105; G06F 13/4234

(57) ABSTRACT

A system of at least two microcontrollers, each of the at least two microcontrollers having a respective hardware interface that is set up for a terminal of a contact connection, and the at least two microcontrollers being functional both when they are coupled by a contact connection in data-transmitting fashion via the hardware interfaces as well as independently. An electronic component, a computing unit, and a method for producing such a system, are also described.

### CROSS REFERENCE

The present application claims the benefit under 35 U.S.C. §119 of German Patent Application No. DE 102015221064.2 filed on Oct. 28, 2015, which is expressly incorporated herein by reference in its entirety.

### FIELD

The present invention relates to a system of at least two microcontrollers, internal structures of the microcontrollers being coupled so as to be capable of transmitting data, in particular for the common use of the respective resources, to an electronic component and a computing unit having such a system, and to a method for producing such a system.

### BACKGROUND INFORMATION

In control devices, for example for controlling machines, plants, passenger or utility vehicles, or in consumer electronics, e.g., mobile telephones or television devices, the individual components of the control device communicate with one another. The task of an engine control device of an internal combustion engine is for example to calculate output quantities for actuating elements (such as injection nozzles or ignition systems) from a large number of input signals (such as rotational speed, temperature, or pressure). For this purpose, a control device has as components integrated circuits (ICs) such as microcontrollers, ASIC, ASSP, etc.

Microcontrollers are small complete computer systems, inter alia having their own processor and memory, fashioned as a single integrated circuit. The term ASIC designates application-specific integrated circuits. The term ASSP designates application-specific standard products.

Due to the complex functions that a microcontroller can execute, this microcontroller is frequently the central component of a control device, and controls all the other components of the control device, in particular other ICs. Usually also stored in the microcontroller are the data, characteristic maps, and/or programs required for operation, including for other components that do not have their own memory or whose own memory is too small.

For various applications, for example the above-named controlling of an internal combustion engine, standardly specific microcontrollers that cover a particular application segment are specified and realized. However, due to high design outlay, and thus high design and production costs, it is often economically not rational to produce or offer microcontrollers that are specified for particular applications but are required only in low piece counts.

### SUMMARY

According to the present invention, a system incldues at least two microcontrollers, an electronic component, a computing unit, and a method for producing a system of at least two microcontrollers. Advantageous embodiments are described herein.

A system according to the present invention has at least two microcontrollers, in particular so-called automotive microcontrollers, i.e., for use in the automotive field, e.g., vehicle control devices). Here, each of the at least two microcontrollers has its own hardware interface that is set up for a terminal of a contact connection, and the at least two microcontrollers can be coupled via the hardware interfaces by a contact connection, so as to be capable of transmitting data. Outwardly, the system thus represents a logical microcontroller that internally is made up of the at least two (physical) microcontrollers. The contact connection can be produced for example by bonding wires, or a wire bond connection, or also by conductive side edges, conductive surface contacts, or vias of the die or substrate, and a corresponding mechanical joining.

In particular, each of the at least two microcontrollers is also capable of functioning by itself, in particular if the contact connection is not present. In this way, it is possible to combine a certain number of microcontrollers so that the resources of all microcontrollers can be used together. In this way it is also possible to use the required number of microcontrollers as needed, thus requiring only a small design outlay, namely for the design of the hardware interface. In particular, it is advantageous that already-existing designs of microcontrollers can be used that merely have to be expanded by the hardware interface. In this way, in comparison to a connection of a plurality of individual chip housings, it is also the case that large structures relating to protection against electrostatic discharges, or driver structures, which would limit the speed of the microcontrollers, are not necessary in the microcontrollers.

These microcontrollers can then continue to be used in standalone fashion, but can also be combined to form larger logical microcontrollers. In this way, low piece counts can also be efficiently produced, and an expensive realization of specific microcontrollers is no longer necessary. In addition, more functionalities and/or more computing power can be realized using two or more microcontrollers than with only one microcontroller.

For example, in this way a microcontroller can be used by itself in a control device for an internal combustion engine having four cylinders, and a system according to the present invention of two such microcontrollers can be used for a control device for an internal combustion engine having eight cylinders. If a microcontroller has, for example, a flash memory having 4 MB, a RAM memory having 512 kB, and two processor cores, then, using a system according to the present invention of two such microcontrollers, a logical microcontroller can for example be provided having a flash memory having 8 MB, a RAM memory having 1024 kB, and four processor cores.

A further advantage of the system according to the present invention is that, due to the contact connection, the microcontrollers that are to be coupled or connected at first do not necessarily have to be produced together or situated next to one another on a common semiconductor substrate. In comparison to a metal connection made on the semiconductor substrate, for example using a mask, for the contact connection no semiconductor substrate connecting the microcontrollers is necessary.

The at least two microcontrollers can preferably each have the same functional scope. In this way, it is possible to provide cost-efficient systems having various functional scopes using only one kind of microcontroller.

Alternatively, it is also preferred if a microcontroller has a functional scope that differs from another microcontroller. In this way, for example using two types of microcontrollers systems can be provided having many different functional scopes.

Advantageously, the at least two microcontrollers can be provided on a common semiconductor substrate. In this way, a very simple production of the system is possible.

Alternatively, it is preferred if the at least two microcontrollers are provided on at least two semiconductor substrates separated from one another. For this purpose, the at least two microcontrollers can indeed be applied on a common semiconductor substrate, for example a wafer, for example during production, but subsequently can for example be individually separated from the common semiconductor substrate. These microcontrollers, which then are also capable of functioning individually, can be connected using the contact connection to form a larger logical microcontroller. The advantage here is that the individual microcontrollers do not necessarily have to be situated next to one another on the common substrate during production. Possibly defective microcontrollers can in this way easily be sorted out, and a microcontroller situated next to a defective microcontroller can be connected to another microcontroller after being separated.

An electronic component according to the present invention has a system according to the present invention. Such an electronic component can be used for the equipping of electronic circuits. On the basis of the advantages already mentioned, a large variability is accordingly enabled in the production of such electronic components, while at the same time the costs for design and development can be kept low.

Particularly advantageous is the use of a system according to the present invention in a computing unit set up in particular for controlling an internal combustion engine, because internal combustion engines often occur in many different specific embodiments, often having only a low piece count. However, a system according to the present invention can also be used in computing units for controlling other functions, both in the automotive field and in other areas.

A method according to the present invention is used to produce a system of at least two microcontrollers. Here, the at least two microcontrollers, each having a hardware interface set up for a terminal of a contact connection, are applied on at least one semiconductor substrate. In addition, the at least two microcontrollers are coupled via the hardware interfaces using a contact connection so as to be capable of transmitting data.

Preferably, the at least two microcontrollers are applied onto a common semiconductor substrate. Alternatively, it is preferred if the at least two microcontrollers are applied onto a common semiconductor substrate and separated before the coupling, or if the at least two microcontrollers are applied on at least two different semiconductor substrates. In both cases, the microcontrollers are thus present on two semiconductor substrates separated from one another; in the first case two separate semiconductor substrates are produced from a common semiconductor substrate for example by sawing.

In order to avoid repetition, with regard to the advantages of the method according to the present invention and of the preferred specific embodiments reference is made to the statements concerning the system according to the present invention.

Advantageously, for the microcontrollers that are coupled, from a plurality of microcontrollers only microcontrollers not having defects are selected. In this way, defective microcontrollers can easily be sorted out, and all other, i.e., all functioning, microcontrollers can be used to produce larger logical microcontrollers. Of course, the separated microcontrollers can also be used individually, for example by providing them with a chip housing.

In comparison to the method in accordance with the present invention, for the production of a system of at least two microcontrollers on the common semiconductor substrate the at least two microcontrollers can be formed in a region of the semiconductor substrate, in particular next to one another, the system of the at least two microcontrollers on the common semiconductor substrate being produced in the same way as if only a single microcontroller were involved, i.e., the production steps being carried out generally in parallel. If a lithography method is used as production method, then the at least two microcontrollers are usefully processed in parallel with each exposure, development, and processing step (e.g., etching, application of metal, etc.).

If reticles are used as masks during the exposure, then the exposure step can also take place separately for each microcontroller, in that first one microcontroller is exposed using a reticle and subsequently another one is. Alternatively, a plurality of microcontrollers can also be exposed simultaneously using a plurality of reticles situated alongside one another, or using a common reticle that bears the structures of a plurality of microcontrollers. Proven designs can be combined on reticles so that for each desired functional scope a reticle is provided on which there are situated masks for a plurality of microcontrollers. Alternatively, one design having one microcontroller can also be provided per reticle.

Although if defective microcontrollers are present a system of a plurality of microcontrollers may as a whole no longer be capable of functioning, here the individual non-defective microcontrollers can still be separated, e.g. by sawing or cutting, possibly using a laser, and used as separate microcontrollers. These can then for example also be placed into a chip housing and used as an electronic component.

Further advantages and embodiments of the present invention are described herein and are shown in the figures.

The present invention is shown schematically on the basis of exemplary embodiments in the figures, and is described in the following with reference to the figures.

### BRIEF DESCRIPTION OF THE DRAWINGS

FIG. 1 schematically shows a system according to the present invention of two microcontrollers in a preferred specific embodiment.

FIG. 2 schematically shows a system according to the present invention of two microcontrollers in another preferred specific embodiment.

### DETAILED DESCRIPTION OF EXAMPLE EMBODIMENTS

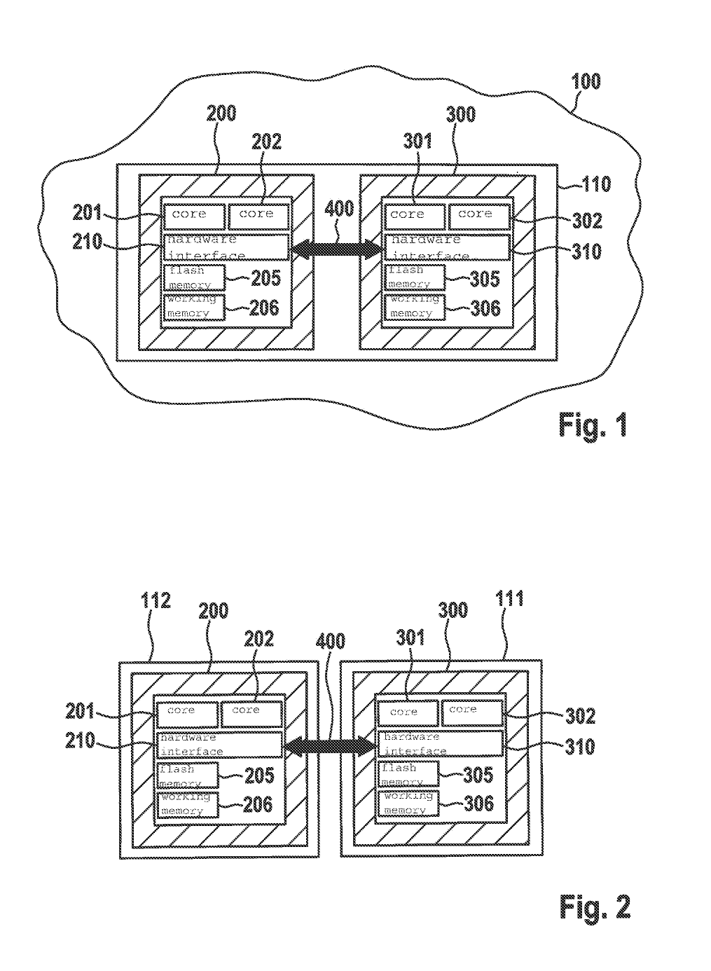

FIG. 1 schematically shows a semiconductor substrate 110 on which two microcontrollers 200, 300 are applied or situated, forming a system according to the present invention in a preferred specific embodiment. As an example, the two microcontrollers 200, 300 are fashioned identically, but the two microcontrollers can also have a different functional scope.

Semiconductor substrate 110, in the sense of a die, can here for example be part of a silicon wafer 100 on which the two microcontrollers 200, 300 are applied during production. Semiconductor substrate 110 can then be separated from silicon wafer 100.

Here, microcontroller 200 includes for example two processor cores 201, 202, a flash memory 205, and a working memory 206. In addition, microcontroller 200 includes a hardware interface 210 via which an external connection is possible, in particular to processor cores 201, 202.

Microcontroller 300 also includes two processor cores 301, 302, a flash memory 305, a working memory 306, and a hardware interface 310. Hardware interfaces 210, 310 are here set up for a terminal of a contact connection, for example a wire bond connection.

The two microcontrollers 200, 300 are situated next to one another on semiconductor substrate 110, and form a system that externally behaves like a single microcontroller. Via hardware interfaces 210, 310 of microcontrollers 200, 300, these microcontrollers are connected by a contact connection 400, for example a wire bond connection.

Microcontrollers 200, 300 are preferably existing (and thus proven and optimized) designs that only have to be expanded by the coupling possibility (i.e., in particular hardware interface and, if needed, a coupler). They are in particular also capable of functioning in individual operation, but can also be coupled to form larger systems according to the present invention. In this way, savings in the design outlay of more than 90% are possible, compared to the design of a new microcontroller having comparable functional scope.

The system is not limited to two microcontrollers; three or more microcontrollers can also be suitably configured on semiconductor substrate 100 and coupled via the hardware interfaces.

FIG. 2 schematically shows two semiconductor substrates 111 and 112 on each of which there is situated a microcontroller 200 or, respectively, 300, forming a system according to the present invention in a further preferred specific embodiment. In themselves, microcontrollers 200, 300 can be formed identically to the specific embodiment shown in FIG. 1.

The two microcontrollers 200, 300 can also form a system that externally behaves like a single microcontroller, and can be connected via hardware interfaces 210, 310 by a contact connection 400, for example a wire bond connection.

In comparison to the specific embodiment shown in FIG. 1, however, the two microcontrollers can be provided not on a common semiconductor substrate, but rather on two separate semiconductor substrates 111 and 112, each in the sense of a die.

During the production, the two microcontrollers 200, 300 can indeed for example be applied on the same silicon wafer, but subsequently the two semiconductor substrates 111, 112 are cut out from the silicon wafer. It is also conceivable that the two semiconductor substrates 111, 112 with microcontrollers 200 or 300 originate from different silicon wafers. In both cases, however, the two microcontrollers 200 and 300 are connected via contact connection 400, so that externally they behave like one logical microcontroller.

In this specific embodiment, the advantage is that for the two microcontrollers 200, 300, microcontrollers can be selected that do not have to be situated next to one another on a silicon wafer. In this way, microcontrollers that have a defect can be sorted out easily.

Here as well, the system is not limited to two microcontrollers; three or more microcontrollers can also be suitably coupled via the hardware interfaces.

What is claimed is:

1. A system, comprising:
at least two microcontrollers, each of the at least two microcontrollers having a respective hardware interface that is set up for a terminal of a contact connection, and, the at least two microcontrollers being functional both when they are coupled to each other by a contact connection in data-transmitting fashion via the hardware interfaces, and are functional independently of one another.

2. The system as recited in claim 1, wherein the at least two microcontrollers being provided on a common semiconductor substrate.

3. The system as recited in claim 1, wherein the at least two microcontrollers are provided on at least two semiconductor substrates separated from one another.

4. The system as recited in claim 1, wherein the system is configured so that when the at least two microcontrollers are coupled to one another by the contact connection so as to be capable of transmitting data, the system behaves externally like a single microcontroller.

5. An electronic component, comprising:
a system including at least two microcontrollers, each of the at least two microcontrollers having a respective hardware interface that is set up for a terminal of a contact connection, and, the at least two microcontrollers being functional both when they are coupled to each other by a contact connection in data-transmitting fashion via the hardware interfaces, and are functional independently of one another.

6. A computing unit, comprising:
a system including at least two microcontrollers, each of the at least two microcontrollers having a respective hardware interface that is set up for a terminal of a contact connection, and, the at least two microcontrollers being functional both when they are coupled to each other by a contact connection in data-transmitting fashion via the hardware interfaces, and are functional independently of one another,
wherein the computing unit being set up to control an internal combustion engine.

7. A method for producing a system of at least two microcontrollers, the method comprising:
applying at least two microcontrollers onto at least one substrate, each of the at least two microcontrollers having a respective hardware interface that is set up for a terminal of a contact connection, the at least two microcontrollers being coupled to each other via the respective hardware interfaces by a contact connection so as to be capable of transmitting data to one another.

8. The method as recited in claim 7, wherein the at least two microcontrollers are applied onto a common semiconductor substrate.

9. The method as recited in claim 7, wherein one of: i) the at least two microcontrollers are applied onto a common semiconductor substrate and are separated before the coupling, or ii) the at least two microcontrollers are applied onto at least two different semiconductor substrates.

10. The method as recited in claim 7, wherein only microcontrollers not having defects are selected from a plurality of microcontrollers for the microcontrollers that are coupled.
